(19) United States
(12) Patent Application Publication
(10) Pub. No.: US 2026/0020379 A1
(43) Pub. Date: Jan. 15, 2026

(54) LED STRUCTURE AND PREPARATION METHOD THEREOF

(71) Applicant: Enkris Semiconductor, Inc., Suzhou (CN)

(72) Inventors: Zhizhong GUO, Suzhou (CN); Liyang ZHANG, Suzhou (CN)

(21) Appl. No.: 19/021,820

(22) Filed: Jan. 15, 2025

(30) Foreign Application Priority Data
Jul. 11, 2024 (CN) 202410926997.7

(51) Int. Cl. H10H 20/813; H10H 20/01; H10H 20/814; H10H 20/825

(52) U.S. Cl. CPC H10H 20/8131; H10H 20/0133; H10H 20/814; H10H 20/825

(57) ABSTRACT

A LED structure includes a first color light-emitting unit, a second color light-emitting unit, a third color light-emitting unit and an optical bonding layer. The first color light-emitting unit and the second color light-emitting unit are located in the same layer and on a light emission side of the third color light-emitting unit. The optical bonding layer is located between the first color light-emitting unit and the third color light-emitting unit and between the second color light-emitting unit and the third color light-emitting unit and is configured to bond the first color light-emitting unit to the third color light-emitting unit and bond the second color light-emitting unit to the third color light-emitting unit. The optical bonding layer is configured to transmit light from the third color light-emitting unit and reflect light from the first color light-emitting unit and the second color light-emitting unit to the light emission side.

### CROSS-REFERENCE TO RELATED APPLICATION

The present application claims priority to Chinese Patent Application No. 202410926997.7, filed with the China National Intellectual Property Administration (CNIPA) on Jul. 11, 2024, the disclosure of which is incorporated herein by reference in its entirety.

### TECHNICAL FIELD

The present invention relates to the technical field of semiconductors and, in particular, to a light-emitting diode (LED) structure and a preparation method thereof.

### BACKGROUND

In the related art, a light-emitting diode (LED) of different emitted colors achieves full colorization through mass transfer or through color conversion using materials such as quantum dots and phosphors. However, the mass transfer is low in the transfer efficiency.

### SUMMARY

The present invention provides an LED structure and a preparation method thereof to achieve the full-color display and improve the light emission efficiency.

According to an aspect of the present invention, an LED structure is provided.

The LED structure includes a first color light-emitting unit, a second color light-emitting unit, a third color light-emitting unit and an optical bonding layer.

The first color light-emitting unit and the second color light-emitting unit are located in a same layer and on a light emission side of the third color light-emitting unit.

The optical bonding layer is located between the first color light-emitting unit and the third color light-emitting unit and between the second color light-emitting unit and the third color light-emitting unit and is configured to bond the first color light-emitting unit to the third color light-emitting unit and bond the second color light-emitting unit to the third color light-emitting unit.

An emission wavelength of the third color light-emitting unit is greater than an emission wavelength of the first color light-emitting unit and an emission wavelength of the second color light-emitting unit, and the optical bonding layer is configured to transmit light from the third color light-emitting unit and reflect light from the first color light-emitting unit and light from the second color light-emitting unit to the light emission side.

According to another aspect of the present invention, a preparation method of an LED structure is provided. The preparation method includes the steps below.

A first color light-emitting unit and a second color light-emitting unit are epitaxially formed, where the first color light-emitting unit and the second color light-emitting unit are located in a same layer.

A third color light-emitting unit is epitaxially formed.

The first color light-emitting unit and the second color light-emitting unit are bonded to the third color light-emitting unit through an optical bonding layer to enable the first color light-emitting unit and the second color light-emitting unit to be located on a light emission side of the third color light-emitting unit, where an emission wavelength of the third color light-emitting unit is greater than an emission wavelength of the first color light-emitting unit and an emission wavelength of the second color light-emitting unit, and the optical bonding layer is configured to transmit light from the third color light-emitting unit and reflect light from the first color light-emitting unit and light from the second color light-emitting unit to the light emission side.

According to technical solutions provided in embodiments of the present invention, the LED structure includes the first color light-emitting unit, the second color light-emitting unit, the third color light-emitting unit and the optical bonding layer. The first color light-emitting unit and the second color light-emitting unit are located in the same layer and on the light emission side of the third color light-emitting unit. The optical bonding layer is located between the first color light-emitting unit and the third color light-emitting unit and between the second color light-emitting unit and the third color light-emitting unit and is configured to bond the first color light-emitting unit to the third color light-emitting unit and bond the second color light-emitting unit to the third color light-emitting unit. The emission wavelength of the third color light-emitting unit is greater than the emission wavelength of the first color light-emitting unit and the emission wavelength of the second color light-emitting unit, and the optical bonding layer is configured to reflect the light from the first color light-emitting unit and the light from the second color light-emitting unit to the light emission side so that the light emission efficiency of the first color light-emitting unit and the second color light-emitting unit can be improved. The optical bonding layer can also transmit the light from the third color light-emitting unit so that the full-color display of the LED structure can be achieved.

### BRIEF DESCRIPTION OF DRAWINGS

FIG. 1 is a diagram illustrating an LED structure according to embodiment one of the present invention.

FIG. 2 is another diagram illustrating an LED structure according to embodiment one of the present invention.

FIG. 3 is a flowchart of a preparation method of an LED structure according to embodiment two of the present invention.

FIG. 4 is a detailed flowchart of S130 in FIG. 3.

FIGS. 5 to 12 are diagrams illustrating the intermediate structures of an LED structure according to embodiment two of the present invention.

FIG. 13 is a detailed flowchart of S110 in FIG. 3.

FIGS. 14 to 17 are other diagrams illustrating the intermediate structures of an LED structure according to embodiment two of the present invention.

FIG. 18 is another flowchart of a preparation method of an LED structure according to embodiment two of the present invention.

FIGS. 19 and 20 are other diagrams illustrating the intermediate structures of an LED structure according to embodiment two of the present invention.

### DETAILED DESCRIPTION

To make the technical solutions of the present invention better understood by those skilled in the art, the technical solutions of embodiments of the present invention are described hereinafter clearly and completely in conjunction with the drawings in embodiments of the present invention. Apparently, the embodiments described hereinafter are part, not all, of embodiments of the present invention. Based on the embodiments of the present invention, all other embodiments obtained by those of ordinary skill in the art are within the scope of the present invention on the premise that no creative work is done.

### Embodiment One

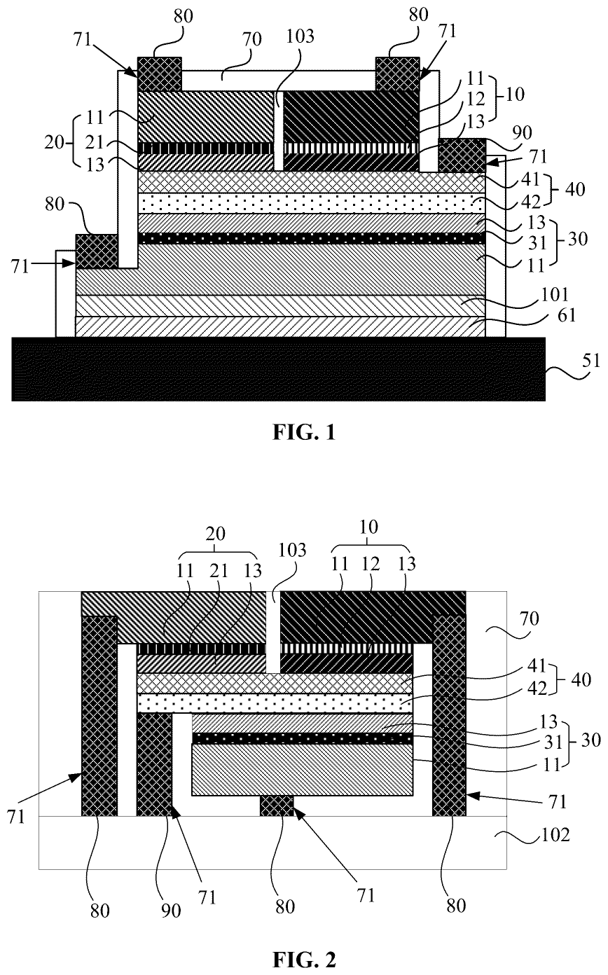

An embodiment of the present invention provides an LED structure. FIG. 1 is a diagram illustrating an LED structure according to embodiment one of the present invention. Referring to FIG. 1, the LED structure includes a first color light-emitting unit 10, a second color light-emitting unit 20, a third color light-emitting unit 30 and an optical bonding layer 40. The first color light-emitting unit 10 and the second color light-emitting unit 20 are located in the same layer and on a light emission side of the third color light-emitting unit 30.

The optical bonding layer 40 is located between the first color light-emitting unit 10 and the third color light-emitting unit 30 and between the second color light-emitting unit 20 and the third color light-emitting unit 30 and is configured to bond the first color light-emitting unit 10 to the third color light-emitting unit 30 and bond the second color light-emitting unit 20 to the third color light-emitting unit 30.

The emission wavelength of the third color light-emitting unit 30 is greater than the emission wavelength of the first color light-emitting unit 10 and the emission wavelength of the second color light-emitting unit 20, and the optical bonding layer 40 is configured to transmit light from the third color light-emitting unit 30 and reflect light from the first color light-emitting unit 10 and light from the second color light-emitting unit 20 to the light emission side.

Specifically, the first color light-emitting unit 10 and the second color light-emitting unit 20 are located in the same layer, so the light emitted from the first color light-emitting unit 10 does not overlap the light emitted from the second color light-emitting unit 20, and the light from the first color light-emitting unit 10 and the light from the second color light-emitting unit 20 may be reflected to the light emission side through the optical bonding layer 40 so that the light emission efficiency of the first color light-emitting unit 10 and the second color light-emitting unit 20 can be improved. The optical bonding layer 40 may transmit the light from the third color light-emitting unit 30 so that the full-color display of the LED structure can be achieved. When the first color light-emitting unit 10 and the second color light-emitting unit 20 need to be controlled separately to emit light, the light from the first color light-emitting unit 10 and the light from the second color light-emitting unit 20 are reflected to the light emission side through the optical bonding layer 40 so that the display effect of the LED structure can be prevented from being affected by light emission of the third color light-emitting unit 30 excited by the first color light-emitting unit 10 and the second color light-emitting unit 20.

Optionally, the first color light-emitting unit 10 may be a blue LED unit, the second color light-emitting unit 20 may be a green LED unit, and the third color light-emitting unit 30 may be a red LED unit. When the first color light-emitting unit 10 is the blue LED unit, a first light-emitting layer 12 of the blue LED unit may be a blue multi-quantum-well layer. When the second color light-emitting unit 20 is the green LED unit, a second light-emitting layer 21 of the green LED unit may be a green multi-quantum-well layer. When the third color light-emitting unit 30 is the red LED unit, a third light-emitting layer 31 of the red LED unit may be a red multi-quantum-well layer. The blue LED unit, the green LED unit and the red LED unit can achieve the colorization of the LED structure, thereby achieving the full-color display.

Optionally, the shape of the perpendicular projection of the first color light-emitting unit 10 on the third color light-emitting unit 30 and the shape of the perpendicular projection of the second color light-emitting unit 20 on the third color light-emitting unit 30 each include any one of a square, a rectangle, or a regular hexagon.

Optionally, referring to FIG. 1, the optical bonding layer 40 includes a conductively optical bonding layer; in the light emission direction, the first color light-emitting unit 10 includes a second semiconductor layer 13, the first light-emitting layer 12 and a first semiconductor layer 11 that are sequentially stacked, and the second semiconductor layer 13 contacts the conductively optical bonding layer; in the light emission direction, the second color light-emitting unit 20 includes a second semiconductor layer 13, the second light-emitting layer 21 and a first semiconductor layer 11 that are sequentially stacked, and the second semiconductor layer 13 contacts the conductively optical bonding layer; in the light emission direction, the third color light-emitting unit 30 includes a first semiconductor layer 11, the third light-emitting layer 31 and a second semiconductor layer 13 that are sequentially stacked, and the second semiconductor layer 13 contacts the conductively optical bonding layer.

The LED structure includes a common first electrode 90. The common first electrode 90 is located on the light emission side of the third color light-emitting unit 30 or a side of the optical bonding layer 40 facing away from the first color light-emitting unit 10 and the second color light-emitting unit 20. The common first electrode 90 is electrically connected to the second semiconductor layers 13 through the optical bonding layer 40.

The conductivity type of each first semiconductor layer 11 is different from the conductivity type of each second semiconductor layer 13, where one is an N-type doped semiconductor layer, and the other is a P-type doped semiconductor layer. The each first semiconductor layer 11 and the each second semiconductor layer 13 are each made of one or more of aluminum nitride (AlN), gallium nitride (GaN), aluminum gallium nitride (AlGaN), or indium gallium nitride (InGaN). A light-emitting layer of each color light-emitting unit is provided with a corresponding color so that the each color light-emitting unit can emit light of the corresponding color. The conductively optical bonding layer is located on a side of the third color light-emitting unit 30 facing the first color light-emitting unit 10 and the second color light-emitting unit 20 and is electrically connected to the second semiconductor layer 13 of the first color light-emitting unit 10, the second semiconductor layer 13 of the second color light-emitting unit 20 and the second semiconductor layer 13 of the third color light-emitting unit 30, so the common first electrode 90 may be disposed through the conductively optical bonding layer. The common first electrode 90 is electrically connected to the second semiconductor layers 13 of the three color light-emitting units through the conductively optical bonding layer so that the process manufacturing cost can be reduced.

Optionally, referring to FIG. 1, when the common first electrode 90 is located on the light emission side of the third color light-emitting unit 30, the third color light-emitting unit 30 further includes a second electrode 80, where the second electrode 80 is located on the light emission side and the surface of the first semiconductor layer 11 facing the third light-emitting layer 31 in the third color light-emitting unit 30; the second color light-emitting unit 20 further includes a second electrode 80, where the second electrode 80 is located on the light emission side and the surface of the first semiconductor layer 11 facing away from the second light-emitting layer 21 in the second color light-emitting unit 20; the first color light-emitting unit 10 further includes a second electrode 80, where the second electrode 80 is located on the light emission side and the surface of the first semiconductor layer 11 facing away from the first light-emitting layer 12 in the first color light-emitting unit 10.

The LED structure further includes a driving substrate electrically connected to the second electrodes 80 and the common first electrode 90. The second electrodes 80 provide the same or different electrical signals for the light-emitting units. The common first electrode 90 provides the same electrical signal for the light-emitting units. The driving substrate may include multiple driving units. The multiple driving units may drive the first color light-emitting unit 10, the second color light-emitting unit 20 and the third color light-emitting unit 30 respectively so that the LED structure can emit light of different colors. The second electrodes 80 and the common first electrode 90 are made of a material, including, but not limited to, gold, silver, or aluminum.

Specifically, referring to FIG. 1, the second semiconductor layer 13 of each light-emitting unit is a P-type semiconductor layer, the first semiconductor layer 11 of the each light-emitting unit is an N-type semiconductor layer, the common first electrode 90 provides the same anode electrical signal for the second semiconductor layer 13 of the each light-emitting unit, and the second electrode 80 of the each light-emitting unit provides a cathode electrical signal for the first semiconductor layer 11 of the each light-emitting unit to separately drive the three light-emitting units. Optionally, referring to FIG. 1, the LED structure further includes a first substrate 51 located on a side of the third color light-emitting unit 30 facing away from the second color light-emitting unit 20, a first buffer layer 61 located between the first substrate 51 and the third color light-emitting unit 30, and a reflective layer 101 located between the first buffer layer 61 and the third color light-emitting unit 30. The first substrate 51 may be made of silicon, sapphire, or another material and play a supporting role, or as a growth substrate, the first substrate 51 is configured to epitaxially manufacture the third color light-emitting unit 30. The first buffer layer 61 may reduce interface defects between the reflective layer 101 and the first substrate 51, or when the first substrate 51 is used as a growth substrate, the first buffer layer 61 may improve the epitaxial crystal quality of the third color light-emitting unit 30. The reflective layer 101 may reflect the light emitted from the third color light-emitting unit 30 to the light emission side so that the light emission efficiency of the third color light-emitting unit 30 can be improved. Optionally, the LED structure further includes a first mask layer 103 located between the first color light-emitting unit 10 and the second color light-emitting unit 20 and disposed in the same layer as the first color light-emitting unit 10 and the second color light-emitting unit 20. The first mask layer 103 may be made of silicon dioxide (SiO₂) or silicon nitride (SiNₓ). Firstly, the first mask layer 103 may be used as a barrier for manufacturing the first color light-emitting unit 10 and the second color light-emitting unit 20. Secondly, the first mask layer 103 may insulate the first color light-emitting unit 10 and the second color light-emitting unit 20 from each other. Lastly, the first mask layer 103 may also avoid mutual interference between the light emitted from the first color light-emitting unit 10 and the light emitted from the second color light-emitting unit 20. In this manner, the display effect of the LED structure can be improved.

Optionally, referring to FIG. 1, the reflective layer 101 is a distributed Bragg reflector (DBR) structure made of gallium arsenide (GaAs)/aluminum gallium arsenide (AlGaAs) and is configured to reflect the light from the third color light-emitting unit so that the display effect of the device can be improved. Optionally, in a DBR of the reflective layer 101, the optical thickness of each GaAs ranges from 100 nm to 200 nm, and the optical thickness of each AlGaAs ranges from 100 nm to 200 nm. Specifically, the value of the refractive index of GaAs multiplied by the physical thickness falls within the preceding optical thickness range, and the value of the refractive index of AlGaAs multiplied by the physical thickness falls within the preceding optical thickness range so that light in the visible light wavelength range can be reflected, thereby achieving total reflection of all visible light by the reflective layer. The third color light-emitting unit 30 may be made of GaAs/AlGaAs, thereby facilitating the manufacturing of the reflective layer and the third color light-emitting unit in the same reflective equipment. Optionally, the number of DBR periods of the reflective layer 101 is greater than the number of stack structures of the optical bonding layer 40 so that the reflection effect of all the light reaching the reflective layer 101 by the reflective layer 101 can be improved.

Optionally, FIG. 2 is another diagram illustrating an LED structure according to embodiment one of the present invention. When the common first electrode 90 is located on the side of the optical bonding layer 40 facing away from the first color light-emitting unit 10 and the second color light-emitting unit 20, the third color light-emitting unit 30 further includes a second electrode 80, where the second electrode 80 is located on the surface of the first semiconductor layer 11 facing away from the third light-emitting layer 31 in the third color light-emitting unit 30; the second color light-emitting unit 20 further includes a second electrode 80, where the second electrode 80 is located on the surface of the first semiconductor layer 11 facing the second light-emitting layer 21 in the second color light-emitting unit 20; the first color light-emitting unit 10 further includes a second electrode 80, where the second electrode 80 is located on the surface of the first semiconductor layer 11 facing the first light-emitting layer 12 in the first color light-emitting unit 10.

The second electrodes 80 provide the same or different electrical signals for the light-emitting units. The common first electrode 90 provides the same electrical signal for the light-emitting units. Since the second electrodes 80 are disposed on the other side of the light emission side, the second electrodes 80 can be prevented from blocking light so that the light emission efficiency of the first color light-emitting unit 10, the second color light-emitting unit 20 and the third color light-emitting unit 30 can be improved.

Optionally, referring to FIG. 2, the projection of the second electrode 80 of the third color light-emitting unit 30 on the plane on which the first color light-emitting unit 10 is located is located between the first color light-emitting unit 10 and the second color light-emitting unit 20.

In the embodiment shown in FIG. 2, a region between the first color light-emitting unit 10 and the second color light-emitting unit 20 affects the light emission efficiency of the third color light-emitting unit 30 below. To avoid reducing the reflection effect of a reflection film below the third color light-emitting unit 30 due to the arrangement of the second electrode 80, the second electrode 80 is disposed in a position corresponding to the region between the first color light-emitting unit 10 and the second color light-emitting unit 20 so that the light emission efficiency of the LED structure can be improved.

Optionally, referring to FIG. 2, the LED structure further includes the driving substrate 102 located on the side of the third color light-emitting unit 30 facing away from the second color light-emitting unit 20, and the common first electrode 90 and the second electrodes 80 contact the driving substrate 102 and are electrically connected to the driving substrate 102.

The driving substrate may include the multiple driving units. The multiple driving units may drive the first color light-emitting unit 10, the second color light-emitting unit 20 and the third color light-emitting unit 30 respectively so that the LED structure can emit the light of different colors.

Optionally, referring to FIGS. 1 and 2, the LED structure further includes an insulating layer 70 located on the same side of the LED structure as the common first electrode 90. The insulating layer 70 is provided with electrode openings 71 at least exposing the common first electrode 90 and the second electrodes 80.

The insulating layer 70 is made of a material including, but not limited to, silicon oxide, silicon nitride, or aluminum oxide. The insulating layer 70 may play an isolation and insulation role.

Optionally, the optical bonding layer 40 includes multiple stack structures. Each stack structure includes a first conductive layer 41 and a second conductive layer 42 that are sequentially stacked. The first conductive layer 41 and the second conductive layer 42 have different refractive indexes.

The first conductive layer 41 and the second conductive layer 42 have the different refractive indexes and are configured to reflect the light emitted from the first color light-emitting unit 10 and the light emitted from the second color light-emitting unit 20 and transmit the light emitted from the third color light-emitting unit.

It is to be noted that FIGS. 1 and 2 show only one set of stack structure made of the first conductive layer 41 and the second conductive layer 42. Optionally, those skilled in the art may select a suitable number of stack structures and types of materials according to the wavelength when the light emitted from the first color light-emitting unit 10 and the light emitted from the second color light-emitting unit 20 are reflected and the wavelength when the light emitted from the third color light-emitting unit 30 is transmitted, which is not limited in the present invention.

Optionally, referring to FIGS. 1 and 2, when the first conductive layer 41 is made of indium tin oxide (ITO), the second conductive layer 42 is made of any one of nickel oxide (NiO), titanium nitride (TiN), or indium zinc oxide (IZO); and/or when the first conductive layer 41 is made of GaN, the second conductive layer 42 is made of AlGaN; and/or when the first conductive layer 41 is made of GaAs, the second conductive layer 42 is made of AlGaAs.

The preceding materials are adopted so that the first conductive layer 41 and the second conductive layer 42 can reflect the light emitted from the first color light-emitting unit 10 and the light emitted from the second color light-emitting unit 20 and transmit the light emitted from the third color light-emitting unit. Optionally, the optical bonding layer may be made of any two sets of the preceding materials. For example, a stack structure facing the first color light-emitting unit and the second color light-emitting unit is made of GaN/AlGaN, and a stack structure facing the third color light-emitting unit is made of ITO and any one of NiO, TiN, or IZO. Alternatively, for example, a stack structure facing the first color light-emitting unit and the second color light-emitting unit is made of ITO and any one of NiO, TiN, or IZO, and a stack structure facing the third color light-emitting unit is made of GaAs/AlGaAs. Optionally, the optical bonding layer may be made of the preceding three sets of materials. For example, the stack structure facing the first color light-emitting unit and the second color light-emitting unit is made of GaN/AlGaN, the stack structure facing the third color light-emitting unit is made of GaAs/AlGaAs, and a stack structure made of ITO and any one of NiO, TiN, or IZO is located between the stack structure made of GaN/AlGaN and the stack structure made of GaAs/AlGaAs.

Optionally, the optical thickness of the first conductive layer 41 and the optical thickness of the second conductive layer 42 each range from 100 nm to 140 nm. Specifically, the value of the refractive index of the first conductive layer 41 multiplied by the physical thickness falls within the optical thickness range, and the value of the refractive index of the second conductive layer 42 multiplied by the physical thickness falls within the optical thickness range so that light in the wavelength range from 400 nm to 560 nm can be reflected, and light in the wavelength range greater than 560 nm can be transmitted, thereby reflecting blue light emitted from the first color light-emitting unit 10 and green light emitted from the second color light-emitting unit 20 and transmitting red light emitted from the third color light-emitting unit 30.

Optionally, one set of optical bonding layer 40 includes 10 to 30 stack structures. Specifically, when the number of stack structures is small, the reflectance of light emitted from the first conductive layer 41 and light emitted from the second conductive layer 42 is low; when the number of stack structures is large, the transmittance of the light emitted from the third color light-emitting unit 30 is reduced. Therefore, 10 to 30 stack structures are selected to form the one set of optical bonding layer 40.

Optionally, referring to FIGS. 1 and 2, the area of the perpendicular projection of the first color light-emitting unit 10 on the third color light-emitting unit 30 is greater than or equal to the area of the perpendicular projection of the second color light-emitting unit 20 on the third color light-emitting unit 30.

The light emission efficiency of the first color light-emitting unit 10 is lower than the light emission efficiency of the second color light-emitting unit 20, so the arrangement of the area of the perpendicular projection of the first color light-emitting unit 10 on the third color light-emitting unit 30 greater than or equal to the area of the perpendicular projection of the second color light-emitting unit 20 on the third color light-emitting unit 30 can improve the light emission efficiency of the first color light-emitting unit 10. The light emission efficiency of the third color light-emitting unit 30 is lower than the light emission efficiency of the first color light-emitting unit 10 and the light emission efficiency of the second color light-emitting unit 20 separately, so the areas of the perpendicular projections of the third color light-emitting unit 30 on the first color light-emitting unit 10 and the second color light-emitting unit 20 are the largest so that the light emission efficiency of the third color light-emitting unit 30 can be improved. Further, the third color light-emitting unit 30 is stacked with the first color light-emitting unit 10 and the second color light-emitting unit 20 so that the area of a single pixel unit can be reduced, and the resolution of the LED structure can be improved, where the single pixel unit includes one third color light-emitting unit, one first color light-emitting unit and one second color light-emitting unit.

### Embodiment Two

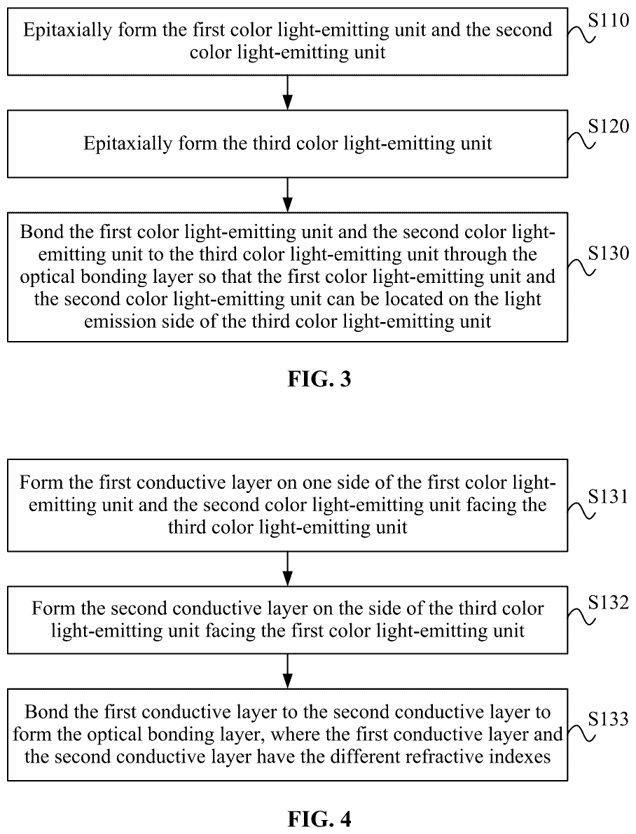

Based on the preceding embodiment, an embodiment of the present invention provides a preparation method of an LED structure. FIG. 3 is a flowchart of a preparation method of an LED structure according to embodiment two of the present invention. Referring to FIG. 3, the preparation method includes the steps below.

In S110, the first color light-emitting unit and the second color light-emitting unit are epitaxially formed, where the first color light-emitting unit and the second color light-emitting unit are located in the same layer.

In S120, the third color light-emitting unit is epitaxially formed.

In S130, the first color light-emitting unit and the second color light-emitting unit are bonded to the third color light-emitting unit through the optical bonding layer so that the first color light-emitting unit and the second color light-emitting unit can be located on the light emission side of the third color light-emitting unit, where the emission wavelength of the third color light-emitting unit is greater than the emission wavelength of the first color light-emitting unit and the emission wavelength of the second color light-emitting unit, and the optical bonding layer is configured to transmit the light from the third color light-emitting unit and reflect the light from the first color light-emitting unit and the light from the second color light-emitting unit to the light emission side.

In the preparation method of an LED structure provided in the technical solution of the embodiment of the present invention, the light emitted from the first color light-emitting unit cannot overlap the light emitted from the second color light-emitting unit, and the first color light-emitting unit and the second color light-emitting unit can reflect the light from the first color light-emitting unit and the light from the second color light-emitting unit to the light emission side through the optical bonding layer so that the light emission efficiency of the first color light-emitting unit and the second color light-emitting unit can be improved; the optical bonding layer can transmit the light from the third color light-emitting unit so that the full-color display of the LED structure can be achieved.

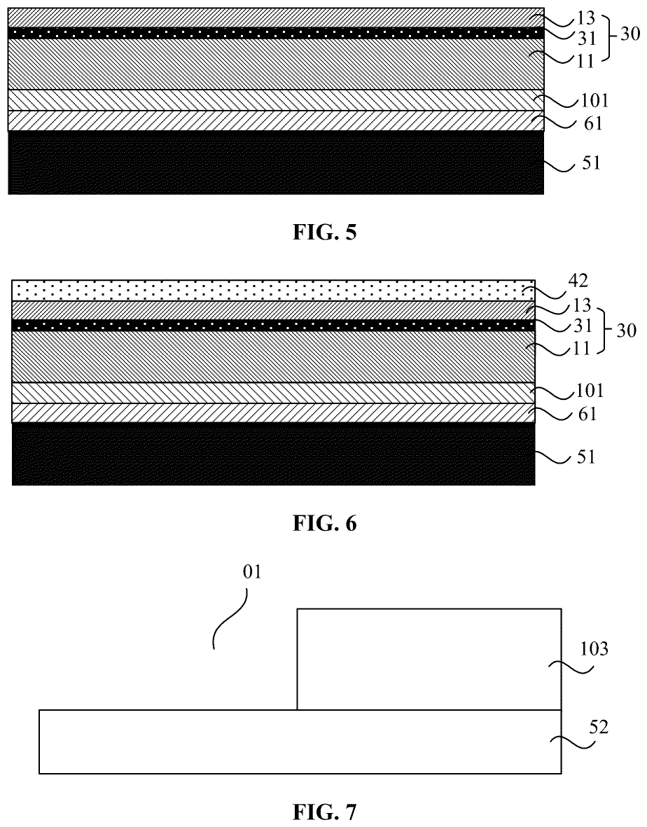

Optionally, FIG. 4 is a detailed flowchart of S130 in FIG. 3, and FIGS. 5 to 12 are diagrams illustrating the intermediate structures of an LED structure according to embodiment two of the present invention. Referring to FIGS. 4 to 12, S130 in which the first color light-emitting unit and the second color light-emitting unit are bonded to the third color light-emitting unit through the optical bonding layer includes the steps below.

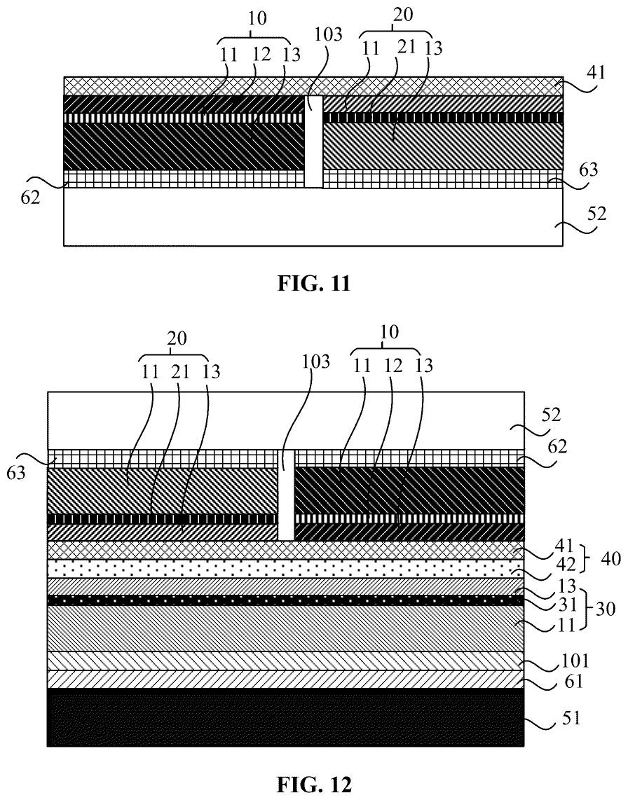

In S131, referring to FIGS. 11 and 12, the first conductive layer 41 is formed on a side of the first color light-emitting unit 10 and the second color light-emitting unit 20 facing the third color light-emitting unit 30.

In S132, referring to FIGS. 6 and 12, the second conductive layer 42 is formed on the side of the third color light-emitting unit 30 facing the first color light-emitting unit 10.

In S133, referring to FIG. 12, the first conductive layer 41 is bonded to the second conductive layer 42 to form the optical bonding layer 40, where the first conductive layer 41 and the second conductive layer 42 have the different refractive indexes.

When the first conductive layer 41 is made of ITO, the second conductive layer 42 is made of any one of NiO, TiN, or IZO; and//or when the first conductive layer 41 is made of GaN, the second conductive layer 42 is made of AlGaN; and/or when the first conductive layer 41 is made of GaAs, the second conductive layer 42 is made of AlGaAs.

Optionally, referring to FIG. 5, before the third color light-emitting unit 30 is epitaxially formed, the preparation method includes that the first buffer layer 61 is formed on the first substrate 51. Optionally, the reflective layer 101 may be formed on a side of the first buffer layer 61 facing away from the first substrate 51. The reflective layer 101 is configured to reflect the light emitted from the third color light-emitting unit 30.

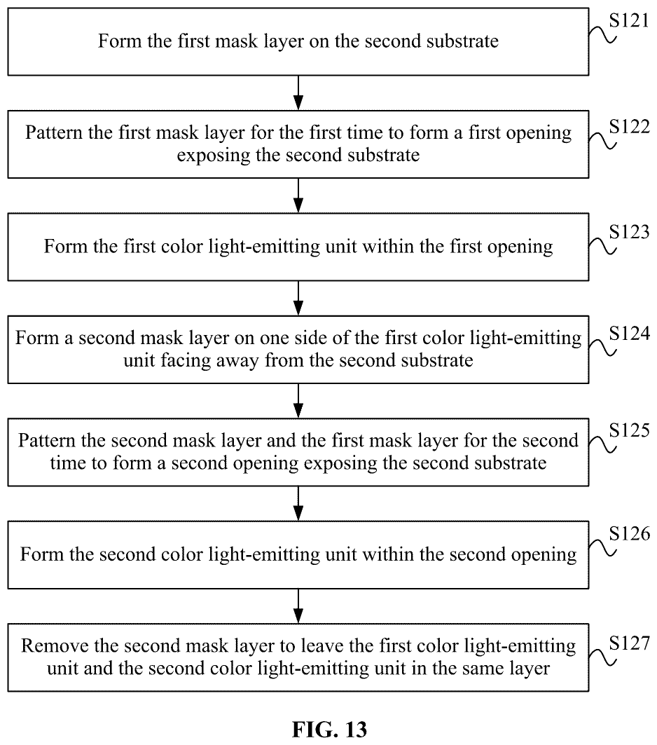

Optionally, FIG. 13 is a detailed flowchart of S110 in FIG. 3. Referring to FIG. 13, S110 in which the first color light-emitting unit 10 and the second color light-emitting unit 20 are epitaxially formed includes the steps below.

In S121, the first mask layer is formed on the second substrate, where the first mask layer is made of a material including, but not limited to, silicon oxide or silicon nitride.

In S122, referring to FIG. 7, the first mask layer 103 is patterned for the first time to form a first opening 01 exposing the second substrate 52.

The first mask layer 103 is patterned for the first time through photolithography and etching to form the first opening 01 exposing the second substrate 52.

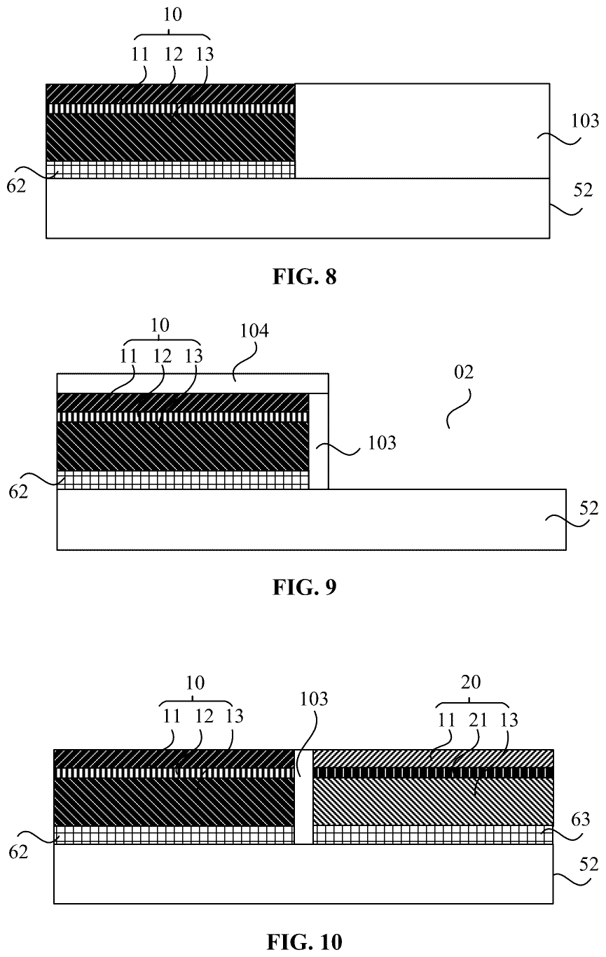

In S123, referring to FIG. 8, the first color light-emitting unit 10 is formed within the first opening 01.

A second buffer layer 62 and the first color light-emitting unit 10 may be sequentially formed within the first opening 01. The second buffer layer 62 may improve the crystal quality of the first color light-emitting unit 10.

In S124, a second mask layer 104 is formed on a side of the first color light-emitting unit 10 facing away from the second substrate 52, where the second mask layer 104 covers the first color light-emitting unit 10 and the first mask layer 103. The second mask layer 104 and the first mask layer 103 are made of the same material.

In S125, referring to FIG. 9, the second mask layer 104 and the first mask layer 103 are patterned for the second time to form a second opening 02 exposing the second substrate 52.

The second mask layer 104 covers the surface of the first color light-emitting unit 10 facing away from the second substrate 52. The first mask layer 103 covers the sidewall of the first color light-emitting unit 10. The second mask layer 104 and the first mask layer 103 are patterned for the second time through photolithography and etching to form the second opening 02 exposing the second substrate 52.

In S126, referring to FIG. 10, the second color light-emitting unit 20 is formed within the second opening 02.

A third buffer layer 63 and the second color light-emitting unit 20 may be formed within the second opening 02. The third buffer layer 63 may improve the lattice quality of the second color light-emitting unit 20.

In S127, referring to FIG. 10, the second mask layer 104 is removed to leave the first color light-emitting unit 10 and the second color light-emitting unit 20 in the same layer.

The second mask layer 104 is removed by etching, and chemical mechanical polishing is performed to make the surface of the first color light-emitting unit 10 facing away from the second substrate 52 flush with the surface of the second color light-emitting unit 20 facing away from the second substrate 52.

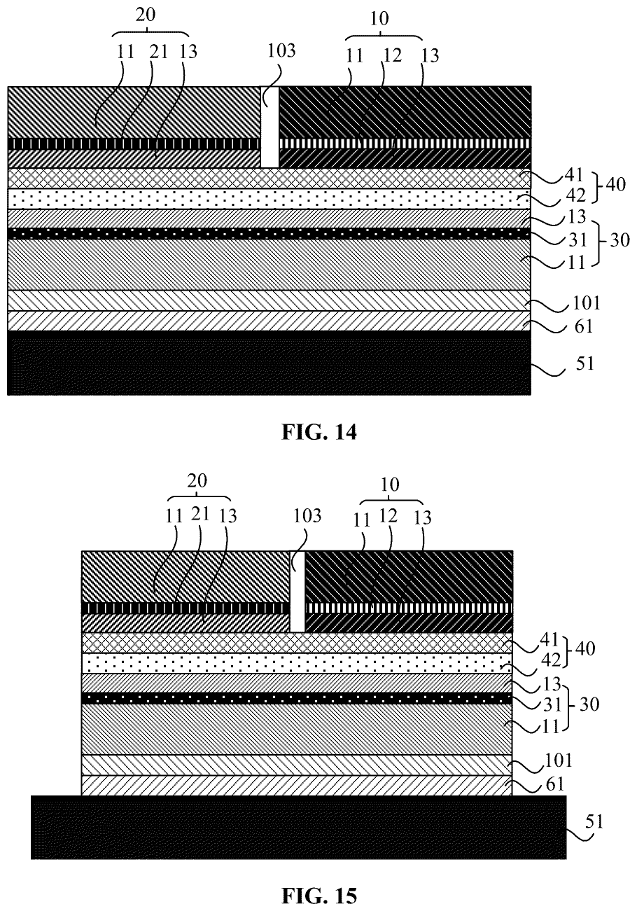

Optionally, FIGS. 14 to 17 are other diagrams illustrating the intermediate structures of an LED structure according to embodiment two of the present invention. Referring to FIGS. 14 to 17, after the first color light-emitting unit 10 and the second color light-emitting unit 20 are bonded to the third color light-emitting unit 30 through the optical bonding layer 40, the preparation method includes a step below.

Referring to FIG. 15, the second substrate 52 is removed.

Through techniques such as thinning and etching, the second substrate 52, the second buffer layer 62 and the third buffer layer 63 that are located on a side of the second substrate, as well as part of the first mask layer 103 are removed; the remaining part of the first mask layer 103 is located between the first color light-emitting unit 10 and the second color light-emitting unit 20 and in the same layer as the first color light-emitting unit 10 and the second color light-emitting unit 20.

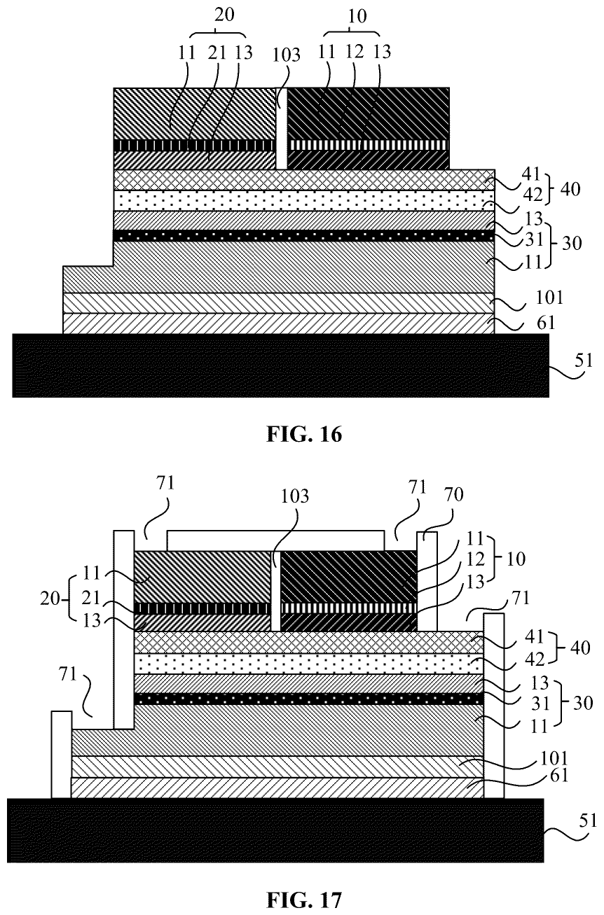

Referring to FIGS. 16 to 18, the insulating layer 70, the common first electrode 90 and the second electrodes 80 are formed on a side of the first color light-emitting unit 10 and the second color light-emitting unit 20 facing away from the first substrate 51, where the insulating layer 70 is provided with the electrode openings 71 at least exposing the common first electrode 90 and the second electrodes 80.

The insulating layer 70 may be formed through physical vapor deposition (PVD), chemical vapor deposition (CVD) and atomic layer deposition (ALD). Referring to FIG. 16, device structures at the edges of two sides of the first substrate 51 are removed to expose the surfaces at the edges of the two sides of the first substrate 51. Referring to FIG. 17, part of the insulating layer 70 deposited on the entire surface is re-etched to expose the surface of the first semiconductor layer 11 of part of the first color light-emitting unit 10, the surface of the first semiconductor layer 11 of part of the second color light-emitting unit 20, the surface of part of the first conductive layer 41 and part of the surface of the first semiconductor layer 11 of the third color light-emitting unit 30. Referring to FIG. 1, the formed electrode openings 71 are provided with the common first electrode 90 and the second electrodes 80.

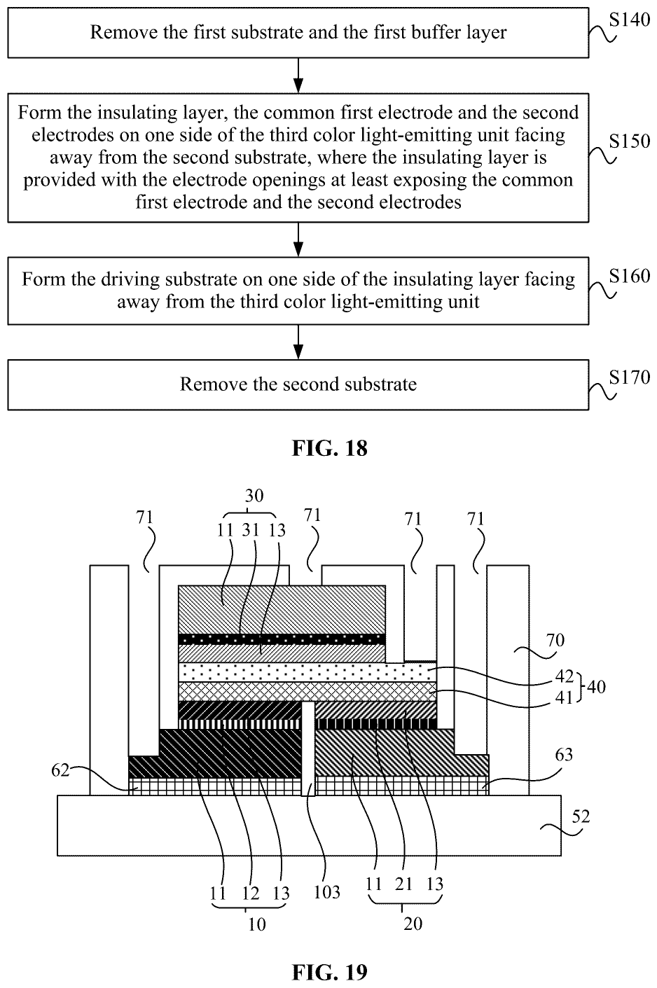

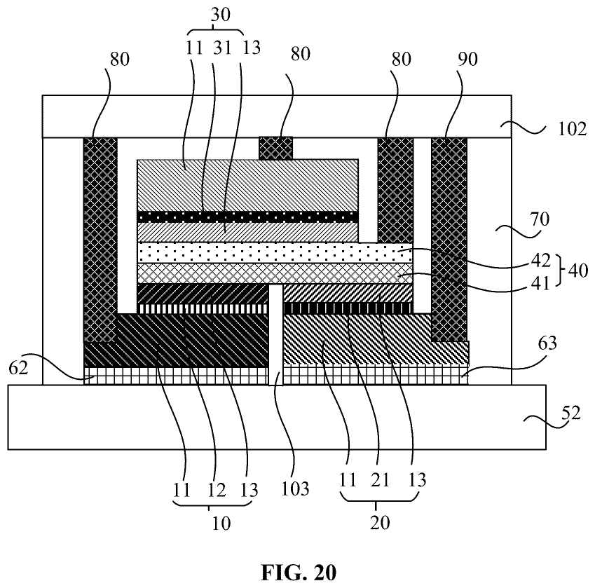

Optionally, FIG. 18 is another flowchart of a preparation method of an LED structure according to embodiment two of the present invention, and FIGS. 19 and 20 are other diagrams illustrating the intermediate structures of an LED structure according to embodiment two of the present invention. Referring to FIGS. 18 to 20, after the first color light-emitting unit 10 and the second color light-emitting unit 20 are bonded to the third color light-emitting unit 30 through the optical bonding layer 40, the preparation method includes the steps below.

In S140, referring to FIGS. 12 and 19, the first substrate 51 and the first buffer layer 61 are removed.

The first substrate 51, the first buffer layer 61 and the reflective layer 101 are removed based on FIG. 12.

In S150, referring to FIGS. 19 and 20, the insulating layer 70, the common first electrode 90 and the second electrodes 80 are formed on a side of the third color light-emitting unit 30 facing away from the second substrate 52, where the insulating layer 70 is provided with the electrode openings 71 at least exposing the common first electrode 90 and the second electrodes 80.

The formed insulating layer 70 exposes the surface of part of the first substrate 51, the surface of the first semiconductor layer 11 of part of the third color light-emitting unit 30, the surface of the first semiconductor layer 11 of part of the second color light-emitting unit 20, the surface of the first semiconductor layer 11 of part of the first color light-emitting unit 10 and the surface of part of the second conductive layer 42. Referring to FIG. 1, the formed electrode openings 71 are provided with the common first electrode 90 and the second electrodes 80.

In S160, referring to FIG. 20, the driving substrate 102 is formed on a side of the insulating layer 70 facing away from the third color light-emitting unit 30, where the common first electrode 90 and the second electrodes 80 contact the driving substrate 102 and are electrically connected to the driving substrate 102.

The driving substrate 102 includes the multiple driving units. The multiple driving units are configured to control the first color light-emitting unit 10, the second color light-emitting unit 20 and the third color light-emitting unit 30, respectively.

In S170, referring to FIG. 2, the second substrate is removed. Optionally, the preceding LED structure is finally formed into the structure in FIG. 2.

The preparation method of an LED structure provided in the embodiments of the present invention has the same beneficial effects as the LED structure provided in any embodiment of the present invention.

It is to be understood that various forms of processes shown in the preceding may be adopted with steps reordered, added, or deleted. The preceding embodiments do not limit the scope of the present invention. It is to be understood by those skilled in the art that various modifications, combinations, sub-combinations, and substitutions may be performed according to design requirements and other factors. Any modification, equivalent substitution, improvement or the like that is made within the spirit and principle of the present invention is within the scope of the present invention.

What is claimed is:

1. A light-emitting diode (LED) structure, comprising:
a first color light-emitting unit, a second color light-emitting unit and a third color light-emitting unit, wherein the first color light-emitting unit and the second color light-emitting unit are located in a same layer and on a light emission side of the third color light-emitting unit; and
an optical bonding layer, wherein the optical bonding layer is located between the first color light-emitting unit and the third color light-emitting unit and between the second color light-emitting unit and the third color light-emitting unit, and the optical bonding layer is configured to bond the first color light-emitting unit to the third color light-emitting unit and bond the second color light-emitting unit to the third color light-emitting unit,
wherein an emission wavelength of the third color light-emitting unit is greater than an emission wavelength of the first color light-emitting unit and an emission wavelength of the second color light-emitting unit, and the optical bonding layer is configured to transmit light from the third color light-emitting unit and reflect light from the first color light-emitting unit and light from the second color light-emitting unit to the light emission side.

2. The LED structure of claim 1, wherein the optical bonding layer comprises a plurality of stack structures, wherein each of the plurality of stack structures comprises a first conductive layer and a second conductive layer that are sequentially stacked, wherein the first conductive layer and the second conductive layer have different refractive indexes.

3. The LED structure of claim 2, wherein:
when the first conductive layer is made of indium tin oxide (ITO), the second conductive layer is made of any one of nickel oxide (NiO), titanium nitride (TiN), or indium zinc oxide (IZO); or
when the first conductive layer is made of gallium nitride (GaN), the second conductive layer is made of aluminum gallium nitride (AlGaN); or
when the first conductive layer is made of gallium arsenide (GaAs), the second conductive layer is made of aluminum gallium arsenide (AlGaAs).

4. The LED structure of claim 2, wherein an optical thickness of the first conductive layer and an optical thickness of the second conductive layer each range from 100 nm to 140 nm.

5. The LED structure of claim 1, wherein the optical bonding layer comprises a conductively optical bonding layer,
in a light emission direction, the first color light-emitting unit comprises a second semiconductor layer, a first light-emitting layer and a first semiconductor layer that are sequentially stacked, wherein the second semiconductor layer contacts the conductively optical bonding layer;
in the light emission direction, the second color light-emitting unit comprises a second semiconductor layer, a second light-emitting layer and a first semiconductor layer that are sequentially stacked, wherein the second semiconductor layer contacts the conductively optical bonding layer;
in the light emission direction, the third color light-emitting unit comprises a first semiconductor layer, a third light-emitting layer and a second semiconductor layer that are sequentially stacked, wherein the second semiconductor layer contacts the conductively optical bonding layer;
the LED structure comprises a common first electrode, wherein the common first electrode is located on the light emission side of the third color light-emitting unit or a side of the optical bonding layer facing away from the first color light-emitting unit and the second color light-emitting unit; and
the common first electrode is electrically connected to the second semiconductor layers through the optical bonding layer.

6. The LED structure of claim 5, wherein:
when the common first electrode is located on the light emission side of the third color light-emitting unit,
the third color light-emitting unit further comprises a second electrode, wherein the second electrode is located on the light emission side and a surface of the first semiconductor layer facing the third light-emitting layer in the third color light-emitting unit;
the second color light-emitting unit further comprises a second electrode, wherein the second electrode is located on the light emission side and a surface of the first semiconductor layer facing away from the second light-emitting layer in the second color light-emitting unit; and
the first color light-emitting unit further comprises a second electrode, wherein the second electrode is located on the light emission side and a surface of the first semiconductor layer facing away from the first light-emitting layer in the first color light-emitting unit.

7. The LED structure of claim 6, further comprising:
a first substrate located on a side of the third color light-emitting unit facing away from the second color light-emitting unit;
a first buffer layer located between the first substrate and the third color light-emitting unit; and
a reflective layer located between the first buffer layer and the third color light-emitting unit.

8. The LED structure of claim 7, wherein the reflective layer is a distributed Bragg reflector (DBR) structure made of GaAs/AlGaAs.

9. The LED structure of claim 8, wherein an optical thickness of each GaAs ranges from 100 nm to 200 nm, and an optical thickness of each AlGaAs ranges from 100 nm to 200 nm.

10. The LED structure of claim 5, wherein:
when the common first electrode is located on the side of the optical bonding layer facing away from the first color light-emitting unit and the second color light-emitting unit, the third color light-emitting unit further comprises a second electrode, wherein the second electrode is located on a surface of the first semiconductor layer facing away from the third light-emitting layer in the third color light-emitting unit;
the second color light-emitting unit further comprises a second electrode, wherein the second electrode is located on a surface of the first semiconductor layer facing the second light-emitting layer in the second color light-emitting unit; and
the first color light-emitting unit further comprises a second electrode, wherein the second electrode is located on a surface of the first semiconductor layer facing the first light-emitting layer in the first color light-emitting unit.

11. The LED structure of claim 10, wherein a projection of the second electrode of the third color light-emitting unit on a plane on which the first color light-emitting unit is located is located between the first color light-emitting unit and the second color light-emitting unit.

12. The LED structure of claim 10, further comprising:
a driving substrate located on a side of the third color light-emitting unit facing away from the second color light-emitting unit,
wherein the common first electrode and the second electrodes contact the driving substrate and are electrically connected to the driving substrate.

13. The LED structure of claim 1, wherein
an area of a perpendicular projection of the first color light-emitting unit on the third color light-emitting unit is greater than or equal to an area of a perpendicular projection of the second color light-emitting unit on the third color light-emitting unit.

14. The LED structure of claim 1, wherein the first color light-emitting unit is a blue LED unit, the second color light-emitting unit is a green LED unit, and the third color light-emitting unit is a red LED unit.

15. The LED structure of claim 1, wherein
a shape of a perpendicular projection of the first color light-emitting unit on the third color light-emitting unit and a shape of a perpendicular projection of the second color light-emitting unit on the third color light-emitting unit each comprise any one of a square, a rectangle, or a regular hexagon.

16. A preparation method of a light-emitting diode (LED) structure, comprising:
epitaxially forming a first color light-emitting unit and a second color light-emitting unit, wherein the first color light-emitting unit and the second color light-emitting unit are located in a same layer;
epitaxially forming a third color light-emitting unit; and
bonding the first color light-emitting unit and the second color light-emitting unit to the third color light-emitting unit through an optical bonding layer to enable the first color light-emitting unit and the second color light-emitting unit to be located on a light emission side of the third color light-emitting unit, wherein an emission wavelength of the third color light-emitting unit is greater than an emission wavelength of the first color light-emitting unit and an emission wavelength of the second color light-emitting unit, and the optical bonding layer is configured to transmit light from the third color light-emitting unit and reflect light from the first color light-emitting unit and light from the second color light-emitting unit to the light emission side.

17. The preparation method of an LED structure of claim 16, wherein bonding the first color light-emitting unit and the second color light-emitting unit to the third color light-emitting unit through the optical bonding layer comprises:
forming a first conductive layer on a side of the first color light-emitting unit and the second color light-emitting unit facing the third color light-emitting unit;
forming a second conductive layer on a side of the third color light-emitting unit facing the first color light-emitting unit; and
bonding the first conductive layer to the second conductive layer to form the optical bonding layer, wherein the first conductive layer and the second conductive layer have different refractive indexes.

18. The preparation method of an LED structure of claim 16, wherein epitaxially forming the first color light-emitting unit and the second color light-emitting unit comprises:
forming a first mask layer on a second substrate;
patterning the first mask layer for a first time to form a first opening exposing the second substrate;
forming the first color light-emitting unit within the first opening;
forming a second mask layer on a side of the first color light-emitting unit facing away from the second substrate, wherein the second mask layer covers the first color light-emitting unit and the first mask layer;
patterning the second mask layer and the first mask layer for a second time to form a second opening exposing the second substrate;
forming the second color light-emitting unit within the second opening; and
removing the second mask layer to leave the first color light-emitting unit and the second color light-emitting unit in the same layer.

19. The preparation method of an LED structure of claim 18, after bonding the first color light-emitting unit and the second color light-emitting unit to the third color light-emitting unit through the optical bonding layer, the method comprising:
removing the second substrate; and
forming an insulating layer, a common first electrode and second electrodes on a side of the first color light-emitting unit and the second color light-emitting unit facing away from a first substrate, wherein the insulating layer is provided with electrode openings at least exposing the common first electrode and the second electrodes.

20. The preparation method of an LED structure of claim 18, after bonding the first color light-emitting unit and the second color light-emitting unit to the third color light-emitting unit through the optical bonding layer, the method comprising:
removing the first substrate;
forming an insulating layer, a common first electrode and second electrodes on a side of the third color light-emitting unit facing away from the second substrate, wherein the insulating layer is provided with electrode openings at least exposing the common first electrode and the second electrodes; and
forming a driving substrate on a side of the insulating layer facing away from the third color light-emitting unit, wherein the common first electrode and the second electrodes contact the driving substrate and are electrically connected to the driving substrate; and
removing the second substrate.
